(19) United States
(12) Patent Application Publication
(10) Pub. No.: US 2025/0215558 A1
(43) Pub. Date: Jul. 3, 2025

(54) METHODS OF FORMING INDIUM MOLYBDENUM OXIDE LAYERS AND ASSOCIATED INDIUM MOLYBDENUM OXIDE LAYERS

(71) Applicant: ASM IP Holding B.V., Almere (NL)

(72) Inventors: Hameeda Jagalur Basheer, Leuven (BE); Andrea IIIiberi, Leuven (BE)

(21) Appl. No.: 19/002,369

(22) Filed: Dec. 26, 2024

Related U.S. Application Data
(60) Provisional application No. 63/615,684, filed on Dec. 28, 2023.

(51) Int. Cl. C23C 16/40; C23C 16/455

(52) U.S. Cl. CPC C23C 16/405; C23C 16/45527; C23C 16/45553

(57) ABSTRACT

Methods of forming indium molybdenum oxide layers (IMO) by vapor deposition are provided. In some embodiments cyclical deposition processes for forming IMO layers comprise alternately and sequentially contacting a substrate in a reaction chamber with a vapor phase indium precursor, a vapor phase molybdenum precursor, and one or more oxygen reactants.

### CROSS-REFERENCE TO RELATED APPLICATION(S)

This Application claims the benefit of U.S. Provisional Application 63/615,684 filed on Dec. 28, 2023, the entire contents of which are incorporated herein by reference.

### FIELD

The present disclosure generally relates to the field of semiconductor processing methods, and to the field of device and integrated circuit manufacture. More particular, the present disclosure relates to vapor deposition processes for forming indium molybdenum oxide layers.

### BACKGROUND OF THE DISCLOSURE

Conductive oxides are increasingly being used in the semiconductor industry. For example, conducting oxides can be employed as the active layer in thin-film transistors (TFTs), as access transistors in 3D NAND/3D DRAM applications, as contact layers to devices, and as the semiconductor layers in metal-semiconductor-metal (MSM) type photodetectors. However, the performance of devices and/or integrated circuits incorporating certain potential conducting oxide materials may be negatively impacted by the materials lack of stability, high resistivity, and low carrier mobility, for example. Accordingly, improved conducting oxide materials and methods for forming such materials are desirable.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming indium molybdenum oxide layers on a surface of a substrate. As set forth in more detail below, the methods described herein can employ cyclical deposition processes and particularly atomic layer deposition processes to form indium molybdenum oxide layers. For example, such indium molybdenum oxide layers can be employed as an electrical contacts for semiconductor device structures.

In particular the present disclosure includes methods of forming an indium molybdenum oxide layer on a substrate within a reaction chamber. In accordance with examples of the disclosure, the disclosed methods include performing a cyclical deposition process including a plurality of repeated deposition cycles. In such examples, a deposition cycle includes (a) contacting the substrate with a vapor phase indium precursor, (b) contacting the substrate with a vapor phase molybdenum precursor, and (c) contacting the substrate with an oxygen reactant.

In some embodiments, the cyclical deposition process is an atomic layer deposition process.

In some embodiments, the deposition cycle includes an indium oxide sub-cycle.

In some embodiments, the indium molybdenum oxide layer comprises a molybdenum doped indium oxide.

In some embodiments, the deposition cycle includes an indium oxide sub-cycle and a molybdenum oxide sub-cycle.

In some embodiments, the oxygen reactant contacts the substrate after step (a), and after step (b).

In some embodiments, the indium molybdenum oxide layer is a mixture of indium oxide and molybdenum oxide.

In some embodiments, the indium oxide sub-cycle is performed in a first reaction chamber and the molybdenum oxide sub-cycle is performed in a second reaction chamber.

In some embodiments, the substrate is heated to a substrate temperature of less than 250° C.

In some embodiments, the indium molybdenum oxide layer has a molybdenum content of between 0.001 atomic-% and 40 atomic-%.

In some embodiments, the vapor phase indium precursor includes a ligand selected from the group consisting of an alkyl, an alkylamino, an alkoxy, a halide, a cyclopentadienyl (Cp), an alkoxide, an amide, an amidinate, a guanidinate, a beta-diketonate, and a triazenude.

In some embodiments, the vapor phase indium precursor is selected from the group consisting of trimethylindium, triethyllindium, ethyldimethylindium, InMe₂(CH₂CH₂CH₂NMe₂), InEt₂(CH₂CH₂CH₂NMe₂), InMe₂(CH₂CH₂CH₂NEt₂), InEt₂(CH₂CH₂CH₂NEt₂), InCl, InCl₃, InMe₂Cl, In(CpCH₂CH₂NMe₂), In(CpCH₂CH₂CH₂NMe₂), InMe₂(CpCH₂CH₂NMe₂), InMe₂(CpCH₂CH₂CH₂NMe₂), In(CpCH₂CH₂OMe), In(CpCH₂CH₂CH₂OMe),. InMe₂(CpCH₂CH₂OMe), InMe₂(CpCH₂CH₂CH₂OMe, tris(tert-pentoxy)indium(III). tris(tert-butoxy)indium(III), tris(isopropoxy)indium(III), In(dmap)₃, where damp is 4-(Dimethylamino)pyridine, In(dmamp)3, where dmamp is 2-(Dimethylamino)-2-methylpropan-1-ol, In(dmamb)₃, where dmamb is Bis(1-dimethylamino-2-methyl-2-butoxy), InMe₂(dmap), InMe₂(dmamp), InMe₂(dmamb), InEt₂(dmap), InEt₂(dmamp), InEt₂(dmamb), In(dmamp)2(OiPr), InMe₂(NMe₂), InMe₂(NEt₂), InMe₂(NEtMe), InEt₂(NMe₂), InEt₂(NEt₂), InEt₂(NEtMe), InMe₂[N(SiMe₃)₂], InEt₂[N(SiMe₃)₂], In(sBu₂AMD)₃, In(tBu₂AMD)₃, In(iPr₂AMD)₃, or In(tPn₂AMD)₃, In(tBu₂FMD)₃, In(iPr₂FMD)₃, In(tPn₂FMD)₃, In(thd)₃, In(acac)₃, In(hfac)₃, and tris(di-tert-butyltriazenido)indium(III) In(sBu₂FMD)₃, and an indium precursor represented by InR₂L, where R is a methyl or ethyl ligand and where L is selected from tBu₂AMD, iPr₂AMD, tPn₂AMD, sBu₂AMD, tBu₂FMD, iPr₂FMD, tPn2FMD, and sBu₂FMD.

In some embodiments, the vapor phase molybdenum precursor is selected from the group consisting of Mo(CO)₆, (Mo(NMe₂)₂(N^{t}Bu)₂), MoCl₄O, MoO₂(acac)₂, Mo(EtBz)₂, molybdenum isopropoxide, MoO2(acac)2, Mo(OⁱPr)5, and MoCl₂O₂.

In some embodiments, the vapor phase oxygen reactant comprises one or more of oxygen (O), molecular oxygen (O₂), water (H₂O), ozone (O₃), and hydrogen peroxide (H₂O₂).

The present disclosure also includes atomic layer deposition (ALD) processes for forming indium molybdenum oxide layers. In accordance with examples of the disclosure, the ALD processes include alternately and sequentially contacting a substrate in a reaction chamber with trimethylindium, a molybdenum precursor, and an oxygen reactant, and repeating the deposition cycle until the indium molybdenum oxide layer has been formed to a desired thickness and composition.

In some embodiments, the molybdenum precursor is selected from the group consisting of Mo(CO)₆, Mo(NMe₂)₂(N^{t}Bu)₂, MoCl₄O, MoO₂(acac)₂, Mo(EtBz)₂, molybdenum isopropoxide, MoO₂(acac)₂, Mo(OⁱPr)₅, and MoCl₂O₂.

In some embodiments, the molybdenum precursor comprises Mo(NMe₂)₂(N^{t}Bu)₂.

In some embodiments, the indium molybdenum oxide layer (IMO layer) comprises a molybdenum doped indium oxide with a molybdenum content of less than 40 atomic-%. In some embodiments, the indium molybdenum oxide layer has a molybdenum content between 0.001 atomic-% and 40 atomic-%.

In some embodiments, the deposition cycle includes an indium oxide sub-cycle and a molybdenum oxide sub-cycle, the indium oxide sub-cycle including contacting the substrate with trimethylindium and a first oxygen reactant, and the molybdenum oxide sub-cycle including contacting the substrate with the molybdenum precursor and a second oxygen reactant.

In some embodiments, the first oxygen reactant comprises ozone (O₃) and the second oxygen reactant comprises water vapor (H₂O).

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF DRAWING FIGURES

To easily identify the discussion of any particular element or act, the most significant digit or digits in a reference number refer to the figure number in which that element is first introduced.

A more complete understanding of exemplary embodiments of the present disclosure can be derived by referring to the detailed description and claims when considered in connection with the following illustrative figures.

FIG. 1 illustrates an exemplary method according to the embodiments of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and structures provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As set forth in more detail below, various embodiments of the disclosure provide methods for forming indium molybdenum oxide layers (referred to herein also as IMO layers, molybdenum doped indium oxide layers, and mixed oxides of indium oxide and molybdenum oxide). Exemplary methods can be used to form IMO layers on a surface of substrate by cyclical deposition processes and particularly atomic layer deposition processes. The cyclical deposition processes of the present can include performing two or more deposition cycles, where each deposition cycle comprises the steps of (a) contacting the substrate with a vapor phase indium precursor (b) contacting the substrate with a vapor phase molybdenum precursor, and (c) contacting the substrate with an oxygen reactant. The steps (a-c) of the deposition cycle can be performed in any order, in parallel (or at least partially in parallel), with multiple repetitions of each step, and with the option of including additional steps within a deposition cycle. In addition, a deposition cycle can comprise a super-cycle, wherein a super-cycle includes one or more sub-cycles, each sub-cycle being employed for forming a component of the IMO layer. The cyclical deposition processes of the present disclosure therefore allow for the controlled formation of IMO layers with the desired material properties, such as, but not limited to, composition, thickness, stoichiometry, conductivity, dopant concentration, etc.

In this disclosure, gas can include material that is a gas at normal temperature and pressure (NTP), a vaporized solid and/or a vaporized liquid, and can be constituted by a single gas or a mixture of gases, depending on the context.

As used herein, the terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. In some cases, the term reactant can be used interchangeably with the term precursor.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material or high k dielectric material is material having a dielectric constant greater than the dielectric constant of silicon dioxide.

As used herein, the term “film” and/or “layer” can used interchangeably and can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g., subdivided, and may be comprised of a plurality of semiconductor devices.

As used herein, the term “cyclic deposition process” or “cyclical deposition process” can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. In some cases, a cyclical deposition process can include continually flowing one or more precursors, reactants, or inert gases, and pulsing other of the precursors or reactants.

As used herein, the term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, when performed with alternating pulses of precursor(s)/reactive gas(es), and purge (e.g., inert carrier) gas(es). Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber.

As used herein, the term “purge” can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be effected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. Further, in this disclosure, the terms including, constituted by and having refer independently to typically or broadly comprising, comprising, consisting essentially of, or consisting of in some embodiments.

In this disclosure, any defined meanings do not necessarily exclude ordinary and customary meanings, in some embodiments.

In accordance with examples of the disclosure, methods of forming indium molybdenum oxide layers by vapor deposition processes, such as atomic layer deposition, are provided. In some embodiments IMO layers may be formed on a substrate by vapor deposition processes comprising alternately and sequentially contacting a substrate with a vapor phase indium precursor, a vapor phase molybdenum precursor, and one or more oxygen reactants. In some embodiments, the IMO layers comprise molybdenum doped indium oxides and/or mixed oxides of indium oxide and molybdenum oxide.

As discussed below, in some embodiments the cyclical deposition processes of the present disclosure includes a deposition cycle which can include (a) contacting the substrate with a vapor phase indium precursor, (b) contacting the substrate with a vapor phase molybdenum precursor, and (c) contacting the substrate with one or more oxygen reactants.

As discussed below, in some embodiments a deposition cycle comprises contacting a substrate with each of an indium precursor and a molybdenum precursor, and contacting the substrate with an oxygen reactant after contacting the substrate with the indium precursor and the molybdenum precursor, where the indium precursor and the molybdenum precursor can be provided in any order.

As discussed below, in some embodiments a deposition cycle comprises contacting the substrate with both the indium precursor and the molybdenum precursor with at some temporal overlap (i.e., in parallel, or at least partially in parallel), and contacting the substrate with an oxygen reactant after contacting the substrate with the indium precursor and the molybdenum precursor.

As discussed below, in some embodiments the cyclical deposition processes of the present disclosure include a deposition cycle which comprises one or more sub-cycles in which an oxide is deposited. In accordance with examples of the disclosure, in some embodiments a binary oxide of either one of an indium oxide or molybdenum oxide can be deposited in a sub-cycle followed by contacting the substrate with a molybdenum precursor or an indium precursor respectively. In accordance with examples of the disclosure, binary oxides of each separate precursor can be deposited in two deposition sub-cycles. In such examples a deposition cycle (i.e., a super-cycle) comprises a first sub-cycle in which an indium oxide is deposited from a vapor-phase indium precursor, and a second sub-cycle in which a molybdenum oxide is deposited from a vapor-phase molybdenum precursor. In accordance with examples of the disclosure, binary oxides of each separate precursor can be deposited in two deposition sub-cycles employing a first oxygen reactant and a second oxygen reactant, where the first oxygen reactant and the second oxygen reactant are different from one another. In such examples a first sub-cycle employing the first oxygen reactant can be performed in a first reaction chamber, and the second sub-cycle employing the second oxygen reactant can be performed in a second reaction chamber, where the first reaction chamber and the second reaction chamber are different from one another.

In some embodiments an additional reactant gas, such as a gas comprising NH₃, N₂O, NO₂, and/or H₂O₂ may be provided in one or more deposition cycles to improve layer properties.

In some embodiments the IMO layer may comprise a mixture of one or more individual oxides, such as an indium oxide and a molybdenum oxide

In some embodiments the IMO layer may comprises a molybdenum doped indium oxide. In some embodiments the IMO layer comprises a molybdenum doped In₂O₃.

In some embodiments the IMO layer may comprise a mixture of one or more binary oxides such as indium oxide and molybdenum oxide. The various oxides can be used to tune the IMO layer to achieve a desired result. For example, the amount of each of indium and molybdenum in the IMO layer can be tuned.

In some embodiments a post-deposition anneal and/or a post deposition treatment may be carried out, for example to improve the electrical properties of the layer. A post-deposition anneal may comprise, for example, annealing in an oxygen environment. The disclosed methods can enable high conformality and full stoichiometry control of IMO layer layers, for example on high aspect ratio 3D structures, as needed for some memory applications.

In some embodiments, the indium molybdenum oxide layer deposited by the disclosed methods can be used as contact layer to a semiconductor device, such as a transistor, for example. This can allow for contacts with low resistivity and high carrier mobility. In some embodiments the IMO layers are deposited at low temperatures (<250° C.) allowing its use in back end of line (BEOL) devices. In some embodiments the IMO layers of the present disclosure can be deposited on three-dimensional structures with high conformality and high uniformity. This can allow for the use of the IMO layers in high aspect ratio devices such as DRAM.

Other contexts in which IMO layers may be utilized will be apparent to the skilled artisan. In some embodiments the IMO layers are not used as a transparent layer transistor (TFT) for use in a display.

As noted above, vapor deposition processes are provided for depositing IMO layers. In some embodiments, cyclical deposition processes, and particularly atomic layer deposition (ALD) techniques are employed to deposit conformal IMO layers. Among vapor deposition techniques, ALD has the advantage of providing high conformality at low temperatures. In some embodiments cyclic CVD process may be utilized. Thus, in some embodiments reaction temperatures may be above the decomposition temperature of at least one precursor. In cyclic CVD reactions at least partial mixing of one or more precursors and reactants may take place. For example, the ALD processes described below could be modified to provide the precursors and reactants simultaneously or in at least partially overlapping pulses in each sub-cycle.

ALD-type processes are based on controlled, surface reactions of precursor chemicals. The surface reactions may or may not be self-limiting. Gas phase reactions may be avoided by feeding the precursors alternately and sequentially into the reaction chamber. Vapor phase reactants are typically separated from each other in the reaction chamber, for example, by removing excess reactants and/or reactant by-products from the reaction chamber between reactant pulses, a process which may be referred to as purging.

Briefly, a substrate is loaded and seated within a reaction chamber and is heated to a suitable substrate temperature (i.e., the deposition temperature), generally at reduced pressure. The substrate may be, for example, a semiconductor substrate. Deposition temperatures can be maintained below the precursor thermal decomposition temperature but at a high enough level to avoid condensation of reactants and to provide the activation energy for the desired surface reactions. Of course, the appropriate temperature window for any given ALD reaction will depend upon the surface termination and reactant species involved.

In some embodiments the deposition temperature (i.e., the substrate temperature) is from about 20° C. to about 600° C., from about to 100° C. to about 400° C., or from about 150° C. to about 300° C., or from about 200° C. to about 250° C. In some embodiments the deposition temperature is less than about 600° C., or less than about 500° C., or less than about 400° C., or less than about 300° C., or less than about 250° C., or less than about 225° C., or less than about 200° C. In some embodiments the deposition temperature is room temperature and 250° C.

The indium precursor and the molybdenum precursor can be individually conducted into the chamber in the form of a vapor phase pulse and contacted with the surface of a substrate. In some embodiments the substrate surface comprises a three-dimensional structure. In some embodiments, conditions are selected such that no more than about one monolayer of each precursor is adsorbed on the substrate surface in a self-limiting manner.

One or more gaseous oxygen reactants are pulsed into the chamber where they react with the indium and/or molybdenum species on the surface to form a respective oxide.

Excess precursor or reactant and reaction byproducts, if any, may be removed from the substrate and substrate surface and from proximity to the substrate and substrate surface between pulses of each precursor or reactant. In some embodiments, reactant and reaction byproducts, if any, may be removed by purging. Purging may be accomplished for example, with a pulse of inert gas such as nitrogen or argon.

Purging the reaction chamber means that vapor phase precursors or reactants and/or vapor phase byproducts are removed from the reaction chamber such as by evacuating the chamber with a vacuum pump and/or by replacing the gas inside the reactor with an inert gas such as argon or nitrogen. Typical purging times are from about 0.05 seconds to about 20 seconds, between about 1 second and about 10 seconds, or between about 1 second and about 2 seconds. However, other purge times can be utilized, such as when depositing layers over extremely high aspect ratio structures or other structures with complex surface morphology. The appropriate pulsing times can be readily determined by the skilled artisan based on the particular circumstances.

In other embodiments excess precursors (or reactants and/or reaction byproducts, etc.) are removed from the substrate surface or from the area of the substrate by physically moving the substrate from a location containing the precursor, reactant and/or reaction byproducts.

The steps of contacting the substrate with each precursor and reactant, such as by pulsing, and removing excess precursor or reactant and reaction byproducts, are repeated until an IMO layer of the desired thickness has been formed on the substrate, with each complete deposition cycle typically leaving no more than about a molecular monolayer.

As mentioned above, each pulse or phase of each deposition cycle may be self-limiting. An excess of reactant precursors can be supplied in each phase to saturate susceptible structure surfaces. Surface saturation ensures reactant occupation of substantially all, or a majority of, available reactive sites (subject, for example, to physical size or “steric hindrance” restraints) and thus ensures excellent step coverage. In some arrangements, the degree of self-limiting behavior can be adjusted by, e.g., allowing some overlap of reactant pulses to trade off deposition speed (by allowing some CVD-type reactions) against conformality. Ideal ALD conditions with reactants well separated in time and space provide near perfect self-limiting behavior and thus maximum conformality, but steric hindrance results in less than one molecular layer per cycle. Limited CVD reactions mixed with the self-limiting ALD reactions can raise the deposition speed. As mentioned above, in some embodiments pulsed CVD processes are used.

In some embodiments, a reaction space can be in a single-wafer ALD reactor or a batch ALD reactor where deposition on multiple substrates takes place at the same time. In some embodiments the substrate on which deposition is desired, such as a semiconductor workpiece, is loaded into a reaction space of a reaction chamber. The reaction chamber may be part of a cluster tool in which a variety of different processes in the formation of an integrated circuit are carried out. In some embodiments a flow-type reactor is utilized. In some embodiments a high-volume manufacturing-capable single wafer ALD reactor is used. In other embodiments a batch reactor comprising multiple substrates is used. For embodiments in which batch ALD reactor are used, the number of substrates is in the range of 10 to 200, in the range of 50 to 150, or in the range of 100 to 130.

In addition to these ALD reactors, many other kinds of reactors capable of ALD growth of layers, including CVD reactors equipped with appropriate equipment and means for pulsing the precursors can be employed. In some embodiments a flow type ALD reactor is used. Reactants are typically kept separate until reaching the reaction chamber, such that shared lines for the precursors are minimized. However, other arrangements are possible.

Suitable batch reactors include, but are not limited to, reactors designed specifically to enhance ALD processes. In some embodiments a vertical batch reactor is utilized in which the boat rotates during processing. Thus, in some embodiments the wafers rotate during processing. In some embodiments in which a batch reactor is used, wafer-to-wafer uniformity is less than 3% (1sigma), less than 2%, less than 1% or even less than 0.5%.

The IMO layer deposition processes described herein can optionally be carried out in a reaction chamber connected to a cluster tool. In a cluster tool, because each reaction chamber is dedicated to one type of process, the temperature of the reaction chamber in each module can be kept constant, which can improve the throughput compared to a reactor in which the substrate is heated up to the process temperature before each run.

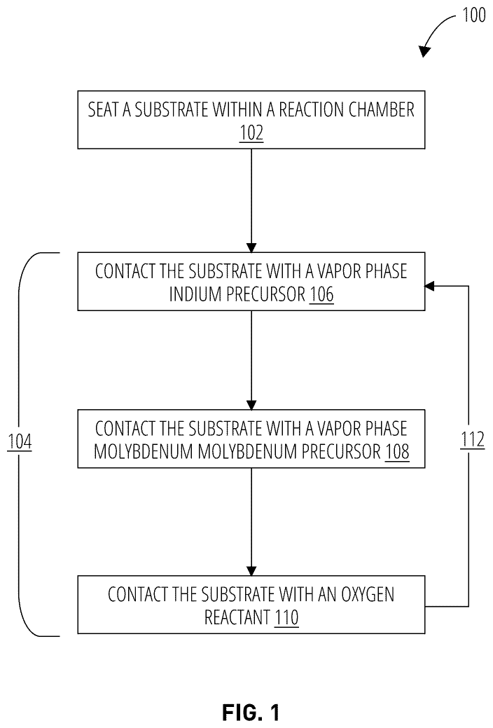

Turning now to the figures, FIG. 1 illustrates a cyclical deposition process 100 comprising a deposition cycle 104. In brief and in accordance with examples of the disclosure, the cyclical deposition process 100 includes seating a substrate within a reaction chamber and heating the substrate to a suitable deposition temperature (step 102), and subsequently performing a plurality of repeated deposition cycles 104, wherein a deposition cycle includes the steps of (a) contacting a substrate with a vapor phase indium precursor (step 106), (b) contacting the substrate with a vapor phase molybdenum precursor (step 108), and (c) contacting the substrate with an oxygen reactant (step 110). The deposition cycle 104 can be repeated (as denoted by cycle loop 112) to deposit an IMO layer of the desired thickness and composition.

In accordance with examples of the disclosure, the deposition cycle 104 can comprise an indium oxide sub-cycle, and/or a molybdenum oxide sub-cycle. In such examples, the oxygen reactant contacts the substrate after step (a) (step 106), and/or after step (b) (step 108). In such examples, the indium oxide sub-cycle can employ a first oxygen reactant, and the molybdenum oxide sub-cycle can employ a second different oxygen reactant. In such examples, the indium oxide sub-cycle can be performed in a first reaction chamber, and the molybdenum oxide sub-cycle can be performed in a second different reaction chamber. In such examples, the first reaction chamber and the second reaction chamber may be part of a clustered semiconductor processing system, and the substrate, in such a system, can be transferred back and forth between the first and second reaction chambers under a control environment (e.g., under an inert gas and/or vacuum) in order to maintain the quality of the deposited layers.

In greater detail and in accordance with examples of the disclosure, in some embodiments at least one of the indium precursor and the molybdenum precursor, are provided prior to the oxygen reactant. In some embodiments each of the indium precursor, and the molybdenum precursor, are provided prior to the oxygen reactant. The indium precursor and the molybdenum precursor may be provided in any order. In some embodiments the precursors are provided sequentially in a deposition cycle in which the substrate is alternately contacted with the indium precursor, and the molybdenum precursor, and the oxygen reactant, in that order. The deposition cycle is repeated to deposit an IMO layer of the desired thickness. The deposition cycle may be written as [indium precursor+molybdenum precursor+oxygen reactant]×N1, where N1 is an integer and the square brackets indicate one deposition cycle, such as an ALD deposition cycle.

In some embodiments the oxygen reactant may be provided after one or more of the indium precursor, and the molybdenum precursor. For example, in some embodiments an IMO layer deposition cycle comprises a super-cycle including two sub-cycles, each of which forms a respective oxide. In a first indium oxide sub-cycle the substrate is alternately and sequentially contacted with the indium precursor and an oxygen reactant. The first sub-cycle may be repeated one, two, or more times. In a second molybdenum oxide sub-cycle, the substrate is alternately and sequentially contacted with a molybdenum precursor and an oxygen reactant. The second sub-cycle may be repeated one, two or more times. The oxygen reactant may be the same in each sub-cycle or may differ in one or more sub-cycles. Although referred to as the first, and second sub-cycles, the sub-cycles may be carried out in any order in the super-cycle. In addition, the number of times that each sub-cycle is carried out may be independently varied in the super-cycle. For example, the number of times that one or more of the sub-cycles is carried out may be varied to achieve a desired composition. The number of times that each sub-cycle is carried out may be the same in each super-cycle or may vary. The super-cycle may be repeated one, two or more times to achieve an IMO layer of the desired thickness and composition. The deposition super-cycle comprising the two sub-cycles may be written as {[indium precursor+oxygen reactant]×N1+[molybdenum precursor+oxygen reactant]×N2}×N3, where N1, N2, and N3 are integers. As will be used throughout the following detailed description below, square brackets represent one ALD sub-cycle whereas the curved brackets represent one super-cycle.

In some embodiments an anneal in an oxygen environment is included in the super-cycle, and the deposition super-cycle comprising the two sub-cycles may be written as {[indium precursor+oxygen reactant]×N1+[molybdenum precursor+oxygen reactant]×N2+[oxygen reactant anneal]×N3}×N4, where N1, N2, N3, and N4 are integers. Such an oxygen reactant anneal step may be included in any of the deposition cycles described herein.

As mentioned above, in some embodiments the IMO layer may comprise a mixture of one or more individual oxides, such as an indium oxide and a molybdenum oxide. In some embodiments, the IMO layer comprises, or consists of, or consists essentially of a mixture of one or more individual oxides, such as an indium oxide and a molybdenum oxide. In some embodiments the IMO layer comprises, or consists of, or consists essentially of a molybdenum doped indium oxide layer. In some embodiments the IMO layer comprises a molybdenum doped In₂O₃ layer.

In some embodiments the stoichiometry of an IMO layer may be tuned by adjusting the ratio of the individual oxides in the layer. In some embodiments a desired stoichiometry of an IMO layer is achieved by selecting the numbers of each sub-cycle within a super-cycle, for example to provide a desired In/Mo ratio.

In some embodiments an additional reactant is included in one or more super-cycles. The additional reactant may, for example, improve the desired electrical properties of the IMO layer. In some embodiments the additional reactant may be used to control the carrier density or concentration. In some embodiments the additional reactant may be used to control defect formation during deposition of the IMO layer. In some embodiments the additional reactant may passivate oxygen vacancies in the growing IMO layer. In some embodiments the additional reactant may comprise one or more of NH₃, N₂O, NO₂ and H₂O₂.

In some embodiments the additional reactant is included in one or more sub-cycles in a super-cycle. In some embodiments the additional reactant is included in each sub-cycle in at least one super-cycle. In some embodiments the additional reactant is provided separately in at least one super-cycle, for example after completing one sub-cycle and before beginning the next.

In each of the sub-cycles described above, the additional reactant may be provided with or after the oxygen reactant. In some embodiments, the additional reactant may be provided alternately and sequentially after the oxygen reactant. For example, a sub-cycle including the additional reactant may be written as [metal precursor (indium or molybdenum)+oxygen reactant+additional reactant]×N1, where N is an integer. In some embodiments, the additional reactant may be provided with the oxygen reactant, as in the sequence: [metal precursor (indium or molybdenum)+(oxygen reactant+additional reactant)]×N1, where N1 is an integer. That is, in some embodiments the additional reactant is provided simultaneously with the oxygen reactant. In some embodiments the additional reactant may be flowed constantly throughout a deposition sub-cycle, or even throughout a deposition super-cycle.

In some embodiments the additional reactant is provided in one or more binary oxide sub-cycles. In some embodiments the additional reactant is provided in an indium oxide sub-cycle. For example, an indium oxide sub-cycle may be written as [indium precursor+oxygen reactant+additional reactant]×N1, where N1 is an integer. In some embodiments the additional reactant is provided in a molybdenum oxide sub-cycle. For example, a molybdenum oxide sub-cycle may be written as [molybdenum precursor+oxygen reactant+additional reactant]×N1, where N1 is an integer. As mentioned above, in some embodiments the additional reactant may be provide simultaneously with the oxygen reactant.

In some embodiments, an IMO layer deposition super-cycle comprises a surface modification step in which the substrate is contacted with a surface modification agent. The surface modification may activate or deactivate surface states on the substrate, thus influencing the amount of precursor that chemisorbs on the substrate in a subsequent step of providing the precursor. The surface modification step may be carried out at any suitable moment in an IMO layer deposition super-cycle. For example, the substrate may be contacted with a surface modification agent before the substrate is contacted with an indium precursor. Additionally or alternatively, the substrate may be contacted with a surface modification agent before the substrate is contacted with a molybdenum precursor. Additionally or alternatively, the substrate may be contacted with a surface modification agent before the substrate is contacted with an oxygen reactant. This can advantageously reduce the growth per cycle of one or more layer constituent sub-cycles in order to enable realization of a given composition with a minimum number of total sub-cycles in a super cycle. In other words, the use of a surface modification agent can improve intermixing and avoid or reduce compositional variability along the growth direction.

In some embodiments, the surface modification step is carried out prior to contacting the substrate with any precursor. In other words, in some embodiments, the substrate is contacted with a surface modification agent before the substrate is contacted with an indium precursor, and/or a molybdenum precursor. In other embodiments, the surface modification step is carried out after performing any of the previous described sub-cycles, such that the surface modification step is performed on a metal oxide (e.g., an indium oxide and a molybdenum oxide)

In some embodiments, the surface modification agent may react with OH groups on the substrate surface. Exemplary surface modification agents include alcohols and acid anhydrides. Suitable alcohols include methanol, ethanol, and/or isopropanol. Suitable acid anhydrides include formic anhydride and acetic anhydride.

In some embodiments, the indium precursor comprises an alkyl ligand. In some embodiments, the alkyl ligand comprises a branched or straight chain hydrocarbyl group containing 1-10 carbon atoms. In some embodiments, the alkyl ligand comprises an alkylamino or alkoxy substituent that can bond to an indium atom through a heteroatom (i.e. N or O). In some embodiments, the ligand is 3-(dimethylamino)propyl or 3-(diethylamino)propyl. In some embodiments, the indium precursor is trimethylindium. In some embodiments, the indium precursor is triethyllindium. In some embodiments, the indium precursor is ethyldimethylindium. In some embodiments, the indium precursor is InMe₂(CH₂CH₂CH₂NMe₂), InEt₂(CH₂CH₂CH₂NMe₂), InMe₂(CH₂CH₂CH₂NEt₂), or InEt₂(CH₂CH₂CH₂NEt₂).

In some embodiments, the indium precursor comprises a halogen ligand. In some embodiments, the halogen ligand is a chloride. In some embodiments, the indium precursor is InCl or InCl₃. In some embodiments, the indium precursor is InMe₂Cl.

In some embodiments, the indium precursor comprises a cyclopentadienyl (Cp) or substituted cyclopentadienyl ligand. In some embodiments, the substituent group on Cp comprises one or more of the following groups: methyl, ethyl, isopropyl, n-propyl, isobutyl, tert-butyl, n-butyl, sec-butyl, trimethylsilyl, pentyl, cyclopentyl, hexyl, cyclohexyl, 2-dimethylaminoethyl, 3-dimethylaminopropyl, 2-methoxyethyl, or 3-methoxypropyl. In some embodiments, the indium molybdenum precursor is InCp. In some embodiments, the indium precursor is In(EtCp). In some embodiments, the indium precursor is In(CpCH₂CH₂NMe₂) or In(CpCH₂CH₂CH₂NMe₂). In some embodiments, the indium precursor is InMe₂(CpCH₂CH₂NMe₂) or InMe₂(CpCH₂CH₂CH₂NMe₂). In some embodiments, the indium precursor is In(CpCH₂CH₂OMe) or In(CpCH₂CH₂CH₂OMe). In some embodiments, the indium precursor is InMe₂(CpCH₂CH₂OMe) or InMe₂(CpCH₂CH₂CH₂OMe).

In some embodiments, the indium precursor comprises an alkoxide ligand. In some embodiments, the alkoxide ligand is isopropoxide. In some embodiments, the alkoxide ligand is tert-butoxide. In some embodiments, the alkoxide ligand is tert-pentoxide. In some embodiments, the ligand is 1-(dimethylamino)-2-propoxide (dmap). In some embodiments, the ligand is 1-(dimethylamino)-2-methyl-2-propoxide (dmamp). In some embodiments, the ligand is 1-(dimethylamino)-2-methyl-2-butoxide (dmamb). In some embodiments, the precursor is tris(tert-pentoxy)indium(III). In some embodiments, the indium precursor is tris(tert-butoxy)indium(III). In some embodiments, the indium precursor is tris(isopropoxy)indium(III). In some embodiments, the indium precursor is In(dmap)₃, In(dmamp)₃, or In(dmamb)₃. In some embodiments, the indium precursor is InMe₂(dmap), InMe₂(dmamp), or InMe₂(dmamb). In some embodiments, the indium precursor is InEt₂(dmap), InEt₂(dmamp), or InEt₂(dmamb). In some embodiments, the indium precursor is In(dmamp)₂(OiPr).

In some embodiments, the indium precursor comprises an amide ligand. In some embodiments, the ligand is dimethylamide. In some embodiments, the ligand is diethylamide. In some embodiments, the ligand is ethylmethylamide. In some embodiments, the ligand is bis(trimethylsilyl)amide. In some embodiments, the indium precursor is InMe₂(NMe₂), InMe₂(NEt₂), or InMe₂(NEtMe). In some embodiments, the indium precursor is InEt₂(NMe₂), InEt₂(NEt₂), or InEt₂(NEtMe). In some embodiments, the indium precursor is InMe₂[N(SiMe₃)₂]. In some embodiments, the indium precursor is InEt₂[N(SiMe₃)₂].

In some embodiments, the indium precursor comprises an amidinate or guanidinate ligand. In some embodiments, the ligand is N,N′-di-tert-butylacetamidinate (tBu₂AMD). In some embodiments, the ligand is N,N′-di-isopropylacetamidinate (iPr₂AMD). In some embodiments, the ligand is N,N′-di-tert-pentylacetamidinate (tPn₂AMD). In some embodiments, the ligand is N,N′-di-sec-butylacetamidinate (sBu2AMD). In some embodiments, the ligand is N,N′-di-tert-butylformamidinate (tBu₂FMD). In some embodiments, the ligand is N,N′-di-isopropylformamidinate (iPr₂FMD). In some embodiments, the ligand is N,N′-di-tert-pentylformamidinate (tPn₂FMD). In some embodiments, the ligand is N,N′-di-sec-butylformamidinate (sBu₂FMD). In some embodiments, the indium precursor is In(sBu₂AMD)₃, In(tBu₂AMD)₃, In(iPr₂AMD)₃, or In(tPn₂AMD)₃. In some embodiments, the indium precursor is In(tBu₂FMD)₃, In(iPr₂FMD)₃, In(tPn₂FMD)₃, or In(sBu₂FMD)₃. In some embodiments, the indium molybdenum precursor is a molecule of the formula InR₂L, where R is a methyl or ethyl ligand and where L is selected from tBu₂AMD, iPr₂AMD, tPn₂AMD, sBu₂AMD, tBu₂FMD, iPr₂FMD, tPn₂FMD, or sBu₂FMD.

In some embodiments, the indium precursor comprises a beta-diketonate ligand. In some embodiments, the ligand is acetylacetonate (acac), 2,2,6,6-tetramethyl-3,5-heptanedionate (thd), or 1,1,1,5,5,5-hexafluoroacetylacetonate (hfac). In some embodiments, the indium precursor is In(thd)3. In some embodiments, the indium precursor is In(acac)3. In some embodiments, the indium precursor is In(hfac)3.

In some embodiments, the indium precursor comprises a triazenide ligand. In some embodiments, the indium precursor is tris(di-tert-butyltriazenido)indium(III).

In accordance with examples of the disclosure, the molybdenum precursor can include one or more of a molybdenum halide, a molybdenum oxyhalide, a molybdenum organometallic compound, a molybdenum metal organic compound, or the like.

In some embodiments, the molybdenum precursor can comprise a molybdenum halide precursor. In further examples, the molybdenum halide precursor can comprise a molybdenum chalcogenide and in some embodiments the molybdenum halide precursor can comprise a molybdenum chalcogenide halide. For example, the molybdenum chalcogenide halide precursor can include a molybdenum oxyhalide selected from a group consisting of a molybdenum oxychloride, a molybdenum oxyiodide, and a molybdenum oxybromide. In example embodiments, the molybdenum halide precursor can comprise a molybdenum oxychloride, including, but not limited to, molybdenum (V) trichloride oxide (MoOCl₃), molybdenum (VI) tetrachloride oxide (MoOCl₄), and molybdenum (IV) dichloride dioxide (MoO₂Cl₂).

In some embodiments, the molybdenum precursor comprises one or more cyclic portions. For example, the molybdenum precursor may comprise one or more benzene rings. In some embodiments, the molybdenum precursor comprises two benzene rings. One or both benzene rings may comprise (e.g., C1-C6) hydrocarbon substituents. In some embodiments, each benzene ring of the molybdenum precursor comprises an alkyl substituent. An alkyl substituent may be a methyl group, an ethyl group, or a linear or branched alkyl group comprising three, four, five or six carbon atoms. For example, the alkyl substituent of the benzene ring may be an n-propyl group or an iso-propyl group. Further, the alkyl substituent may be an n-, iso-, tert- or sec-form of a butyl, pentyl or hexyl moiety. In some embodiments, the molybdenum precursor comprises, consists essentially of, or consists of bis(ethylbenzene)molybdenum (Mo(EtBz)2).

In some embodiments, the molybdenum precursor comprises a cyclopentadienyl (Cp) ligand. For example, the molybdenum precursor may comprise, consist essentially of, or consist of MoCp₂Cl₂ or MoCp₂H₂, Mo(iPrCp)₂Cl₂, Mo(iPrCp)₂H₂, Mo(EtCp)₂H₂.

In some embodiments, the molybdenum precursor comprises at least one alkyl ligand, such as C1 to C4 alkyl, such as methyl, ethyl, propyl, or butyl. In some embodiments, the molybdenum precursor comprises at least one alkoxide ligand, such as C2 to C4 alkoxide, such as ethoxide, propoxide, isopropoxide, n-butoxide. In some embodiments, the molybdenum may comprise, consist essential of, or consist of molybdenum isopropoxide.

In some embodiments of the disclosure, the molybdenum precursor comprises a metal organic compound comprising nitrogen. In some embodiments, the molybdenum precursor comprises a metal organic compound including at least one of an amido group and an imido group. In some embodiments, the molybdenum precursor comprises a metal organic compound including at least one of a tert-butylimido group and a dimethylamido group. In some embodiments, the molybdenum precursor comprises a molybdenum atom which is attached to a nitrogen. In some embodiments, the molybdenum attached is attached to an imido nitrogen in the molybdenum precursor. In some embodiments, the molybdenum precursor comprises bis(tert-butylimido)bis(dimethylamido)molybdenum (Mo(NMe₂)₂(N^{t}Bu)₂). In some embodiments, the molybdenum precursor consist essentially of, or consists of bis(tert-butylimido)bis(dimethylamido)molybdenum.

Additional exemplary molybdenum precursors include molybdenum hexacarbonyl (Mo(CO)₆), tetrachloro(cyclopentadienyl)molybdenum, Mo(tBuN)₂(NMe₂)₂, Mo(NBu)₂(StBu)₂, (Me₂N)₄Mo, (iPrCp)₂MoH₂, Mo(NMe₂)₄, Mo(NEt₂)₄, Mo₂(NMe₂)₆, Mo(tBuN)₂(NMe₂)₂, Mo(NtBu)₂(StBu)₂, Mo(NtBu)₂(iPr₂AMD)₂, Mo(thd)₃, MoO₂(acac)₂, MoO₂(thd)₂, MoO₂(iPr₂AMD)₂, Mo(Cp)₂H₂, Mo(iPrCp)₂H₂, Mo(η₆-ethylbenzene)₂, MoCp(CO)₂(η₃-allyl), and MoCp(CO)₂(NO).

In some embodiments the oxygen reactant comprises one or more of water, ozone, H₂O₂, oxygen (O), molecular oxygen (O₂), oxygen radicals, oxygen plasma, NO₂, N₂O and other compounds comprising N and O, but not metals or semimetals. In some embodiments the oxygen reactant is water. In some embodiments the oxygen reactant is ozone. In some embodiments, such as those described above, one or more oxygen reactants are used in the deposition processes to react with one or more indium, or molybdenum precursors to form the indium molybdenum oxide layer. For example, the oxygen reactant may be used in a binary oxide sub-cycle with one of an indium, or molybdenum precursor. In accordance with examples of the disclosure, a first oxygen reactant is used in an indium oxide sub-cycle and a second oxygen is used in a molybdenum oxide sub-cycle. In some embodiments, the first oxygen reactant and the second oxygen reactant are the same. In some embodiments, the first oxygen reactant and the second oxygen reactant are the different.

In some embodiments an IMO layer is deposited to a thickness of 200 nm or less, about 100 nm or less, about 50 nm or less, about 30 nm or less, about 20 nm or less, about 10 nm or less, about 5 nm or less or about 3 nm or less. In some embodiments, an IMO is deposited to a thickness of less than 1000 nm, less than 750 nm, less than 500 nm, or less than 250 nm, or less than 100 nm, The IMO layer will comprise at least the material deposited in one deposition cycle, or least 2 deposition cycles, or at least 10 deposition cycles, or at least 100 deposition cycles, or at least 1000 deposition cycles.

Atomic layer deposition allows for conformal deposition of IMO layers. In some embodiments, the IMO layers are deposited on a three-dimensional structure and IMO layers have at least 90%, 95% or higher conformality. In some embodiments the IMO layers are about 100% conformal.

In some embodiments, the IMO layer formed has step coverage of more than about 80%, more than about 90%, and more than about 95% in structures which have high aspect ratios. In some embodiments high aspect ratio structures have an aspect ratio that is more than about 3:1 when comparing the depth or height to the width of the feature. In some embodiments the structures have an aspect ratio of more than about 5:1, an aspect ratio of 10:1, an aspect ratio of 20:1, an aspect ratio of 40:1, an aspect ratio of 60:1, an aspect ratio of 80:1, an aspect ratio of 100:1, an aspect ratio of 150:1, an aspect ratio of 200:1 or greater.

In some embodiments, the IMO layers formed have a carbon impurity concentration of less than 20 at-%, less than 10 at-%, less than 5 at-%, less than 2 at-%, less than 1 at-% or less than 0.5 at-%. In some embodiments, the IMO layer layers formed have a hydrogen impurity concentration less than 30 at-%, less than 20 at-%, less than 10 at-%, less than 5 at-%, less than 3 at-% or less than 1 at-%.

In some embodiments, an IMO layer formed by the methods of the disclosure has a indium content (at-%) of less than 80 at-%, or less than 70 at-%, or less than 60 at-%, or less than 50 at-%, or less than 40 at-%, or less than 30 at-%, or less than 20 at-%, or less than 10 at-%. In some embodiments, a MIZO layer formed by the methods of the disclosure has a indium content (at-%) between 80 at-% and 10 at-%, or between 70 at-% and 20 atom-%, or between 60 atom-% and 30 at-%.

In some embodiments, an IMO layer formed by the methods of the disclosure has a molybdenum content (at-%) of less than 40 at-%, or less than 30 at-%, or less than 20 at-%, or less than 15 at-%, or less than 10 at-%, or less than 5 at-%, or less than 1 at-%, or less than 0.1 at-%, or less than 0.01 at-%, or less than 0.001 at-%, or between 0.001 at-% and 40 at-%.

In some embodiments, the IMO layer formed has thickness non-uniformity of less than 10%, less than 5%, less than 2%, less than 1% or less than 0.5% (1 sigma standard deviation) in 200 or 300 mm wafers or other substrates like square substrates.

In some embodiments, the IMO layer formed has elemental compositional non-uniformity (metal atom concentration non-uniformity) across the direction of the substrate surface of less than 30%, less than 20%, less than 10%, less than 5%, less than 2%, less than 1% or less than 0.5% (1 sigma standard deviation) in 200 or 300 mm wafers or other substrates like square substrates.

In some embodiments, the IMO layers deposited by processes disclosed herein are annealed after the deposition, as desired depending on the application. In some embodiments the IMO layers are annealed in an oxygen environment. For example, the layers may be annealed at an elevated temperature in water, O₂ or any of the other oxygen reactants mentioned above. In some embodiments the layers may be annealed in an oxygen reactant comprising oxygen plasma, oxygen radicals, atomic oxygen or excited species of oxygen. In some embodiments the IMO layers are annealed in a hydrogen containing environment or in an inert atmosphere, such as a N2, Ar or He atmosphere. In some embodiments, the layers are annealed in forming gas. In some embodiments an annealing step is not carried out.

In some embodiments, following IMO layer deposition, a further layer is deposited. The additional layer may be deposited directly over and contacting the ALD-deposited IMO layer.

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

What is claimed is:

1. A method of forming an indium molybdenum oxide layer (IMO layer) on a substrate within a reaction chamber, the method comprising:
performing a cyclical deposition process comprising a plurality of repeated deposition cycles, wherein a deposition cycle comprises;
(a) contacting the substrate with a vapor phase indium precursor;
(b) contacting the substrate with a vapor phase molybdenum precursor; and
(c) contacting the substrate with an oxygen reactant.

2. The method of claim 1, wherein the cyclical deposition process comprises an atomic layer deposition process.

3. The method of claim 2, wherein the deposition cycle comprises an indium oxide sub-cycle.

4. The method of claim 3, wherein the indium molybdenum oxide layer comprises a molybdenum doped indium oxide.

5. The method of claim 2, wherein the deposition cycle comprises an indium oxide sub-cycle and a molybdenum oxide sub-cycle.

6. The method of claim 5, wherein the oxygen reactant contacts the substrate after step (a), and after step (b).

7. The method of claim 6, wherein the indium molybdenum oxide layer is a mixture of indium oxide and molybdenum oxide.

8. The method of claim 7, where the indium oxide sub-cycle is performed in a first reaction chamber and the molybdenum oxide sub-cycle is performed in a second reaction chamber.

9. The method of claim 2, wherein the substrate is heated to a substrate temperature is less than 250° C.

10. The method of claim 1, wherein the indium molybdenum oxide layer has a molybdenum content between 0.001 atomic-% and 40 atomic-%.

11. The method of claim 1, wherein the vapor phase indium precursor comprises a ligand selected from a group consisting of an alkyl, an alkylamino, an alkoxy, a halide, a cyclopentadienyl (Cp), an alkoxide, an amide, an amidinate, a guanidinate, a beta-diketonate, and a triazenude.

12. The method of claim 11, wherein the vapor phase indium precursor is selected from the group consisting of trimethylindium, triethyllindium, ethyldimethylindium, InMe₂(CH₂CH₂CH₂NMe₂), InEt₂(CH₂CH₂CH₂NMe₂), InMe₂(CH₂CH₂CH₂NEt₂), InEt₂(CH₂CH₂CH₂NEt₂), InCl, InCl₃, InMe₂Cl, In(CpCH₂CH₂NMe₂), In(CpCH₂CH₂CH₂NMe₂), InMe₂(CpCH₂CH₂NMe₂), InMe₂(CpCH₂CH₂CH₂NMe₂), In(CpCH₂CH₂OMe), In(CpCH₂CH₂CH₂OMe),. InMe₂(CpCH₂CH₂OMe), InMe₂(CpCH₂CH₂CH₂OMe, tris(tert-pentoxy)indium(III). tris(tert-butoxy)indium(III), tris(isopropoxy)indium(III), In(dmap)₃, In(dmamp)₃, In(dmamb)₃. InMe₂(dmap), InMe₂(dmamp), InMe₂(dmamb), InEt₂(dmap), InEt₂(dmamp), InEt₂(dmamb), In(dmamp)₂(OiPr), InMe₂(NMe₂), InMe₂(NEt₂), InMe₂(NEtMe), InEt₂(NMe₂), InEt₂(NEt₂), InEt₂(NEtMe), InMe₂[N(SiMe₃)₂], InEt₂[N(SiMe₃)₂], In(sBu₂AMD)₃, In(tBu₂AMD)₃, In(iPr₂AMD)₃, or In(tPn₂AMD)₃, In(tBu₂FMD)₃, In(iPr₂FMD)₃, In(tPn₂FMD)₃, In(thd)₃, In(acac)₃, In(hfac)₃, and tris(di-tert-butyltriazenido)indium(III) In(sBu₂FMD)₃, and an indium precursor represented by InR₂L, where R is a methyl or ethyl ligand and where L is selected from tBu₂AMD, iPr₂AMD, tPn₂AMD, sBu₂AMD, tBu₂FMD, iPr₂FMD, tPn₂FMD, and sBu₂FMD.

13. The method of claim 1, wherein the vapor phase molybdenum precursor is selected from the group consisting of Mo(CO)₆, (Mo(NMe₂)₂(N^{t}Bu)₂), MoCl₄O, MoO₂(acac)₂, Mo(EtBz)₂, molybdenum isopropoxide, MoO₂(acac)₂, Mo(OⁱPr)5, and MoCl₂O₂.

14. The method of claim 1, wherein the oxygen reactant comprises one or more of oxygen (O), molecular oxygen (O₂), water (H₂O), ozone (O₃), and hydrogen peroxide (H₂O₂).

15. An atomic layer deposition (ALD) process for forming an indium molybdenum oxide layer, the ALD process comprising a deposition cycle comprising alternately and sequentially contacting a substrate in a reaction chamber with trimethylindium, a molybdenum precursor, and an oxygen reactant, and repeating the deposition cycle until the indium molybdenum oxide layer has been formed to a desired thickness and composition.

16. The process of claim 15, wherein the molybdenum precursor is selected from the group consisting of Mo(CO)₆, Mo(NMe₂)₂(N^{t}Bu)₂, MoCl₄O, MoO₂(acac)₂, Mo(EtBz)2, molybdenum isopropoxide, MoO2(acac)2, Mo(OⁱPr)5, and MoCl₂O₂.

17. The process of claim 16, wherein the molybdenum precursor comprises Mo(NMe₂)₂(N^{t}Bu)₂.

18. The process of claim 15, wherein the indium molybdenum oxide layer comprises a molybdenum doped indium oxide with a molybdenum content between 0.001 atomic-% and 40 atomic-%.

19. The process of claim 15, wherein the deposition cycle comprises an indium oxide sub-cycle and a molybdenum oxide sub-cycle, the indium oxide sub-cycle comprising contacting the substrate with trimethylindium and a first oxygen reactant, and the molybdenum oxide sub-cycle comprises contacting the substrate with the molybdenum precursor and a second oxygen reactant.

20. The process of claim 19, wherein the first oxygen reactant comprises ozone (O₃) and the second oxygen reactant comprises water vapor (H₂O).
